(19) United States
(12) Patent Application Publication
(10) Pub. No.: US 2024/0038961 A1
(43) Pub. Date: Feb. 1, 2024

(54) Packaged light-emitting element

(71) Applicant: ProLight Opto Technology Corporation, Taoyuan City (TW)

(72) Inventors: Jung-Hao Hung, Taoyuan City (TW); Meng-Ting Hsieh, Taoyuan City (TW)

(73) Assignee: ProLight Opto Technology Corporation, Taoyuan City (TW)

(21) Appl. No.: 18/143,079

(22) Filed: May 4, 2023

(30) Foreign Application Priority Data
Aug. 1, 2022 (TW) 111208246

(51) Int. Cl. H01L 33/64; H01L 33/62

(52) U.S. Cl. CPC H01L 33/647; H01L 33/62

(57) ABSTRACT

The invention provides a packaged light-emitting element, which comprises a substrate, wherein the substrate comprises a front surface and a back surface; a light-emitting element is located on the front surface of the substrate, and a plurality of metal pillars buried in the substrate.

### BACKGROUND OF THE INVENTION

### 1. Field of the Invention

This invention relates to the optics field in particular to a packaged light-emitting element with low thickness and good thermal conductivity.

### 2. Description of the Prior Art

At present, the thickness of the substrate used in LED packages is mostly between 0.15 mm and 0.5 mm, mainly made of ceramic or plastic. However, with the popularity of electronic wearable products, the demand for thinning electronic products has become a trend, and LED packages are naturally required to be thinner. At the same time, the heat conduction and service life of LEDs must be taken into account.

At present, the common substrate of LED is mainly ceramic or plastic, among which ceramic has the advantage of high thermal conductivity, but the disadvantage is that its thickness needs to be more than 0.4 micron, otherwise it will be easily broken. On the contrary, the plastic substrate can be made thinner than 0.2 micron in thickness, but its thermal conductivity is relatively poor.

### SUMMARY OF THE INVENTION

From the above issues, it can be seen that how to make the substrate packaging the light-emitting element have both ultra-thin (<0.1 micron) and high thermal conductivity is the subject to be solved at present.

The invention provides a packaged light-emitting element, which comprises a substrate, wherein the substrate comprises a front surface and a back surface, a light-emitting element is located on the front surface of the substrate, and a plurality of metal pillars are buried in the substrate.

The present invention is characterized in that polyimide (PI) is used instead of ceramic or plastic as the substrate material for packaging light-emitting elements, in which PI has the characteristics of high temperature resistance, non-absorbent and soft material, which makes the LED package more heat-resistant and moisture-resistant, while the soft texture helps to prevent tin cracking in the cold and hot shock environment, and it will be more advantageous for high reliability standard requirements (such as automotive products). In addition, the PI layer has better ductility, so the substrate can be made thinner. At the same time, in order to improve the heat conduction effect, a number of metal pillars are embedded in the PI substrate to improve the heat dissipation effect and toughness of the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic cross-sectional structure of a packaged light-emitting element according to a first preferred embodiment of the present invention.

FIG. 2 shows a schematic cross-sectional structure of a packaged light-emitting element according to a second preferred embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the Figures are only for illustration and the Figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

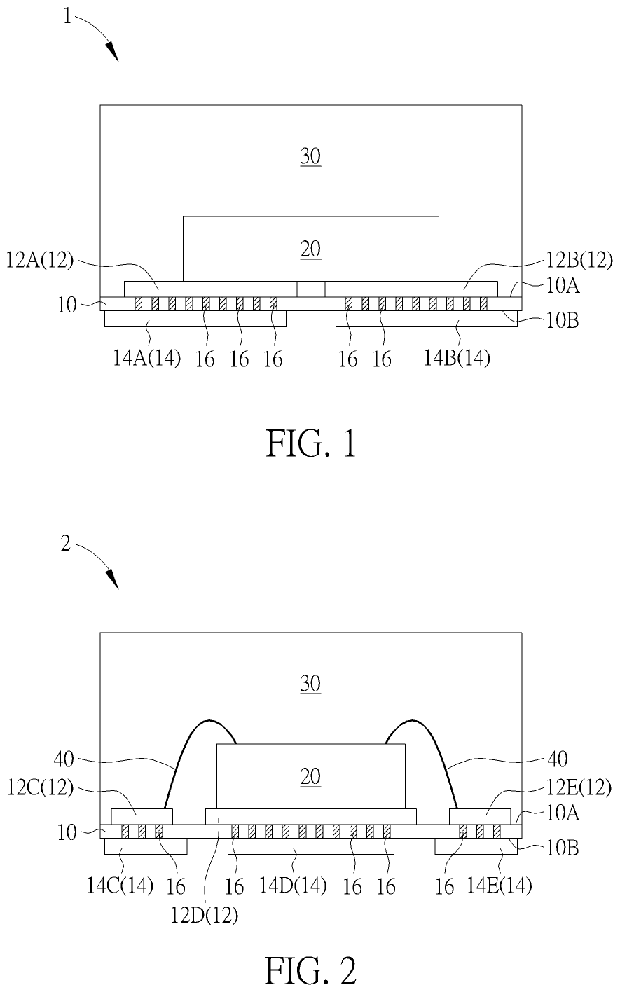

Please refer to FIG. 1, which shows a schematic cross-sectional structure of a packaged light-emitting element according to the first preferred embodiment of the present invention. As shown in FIG. 1, the packaged light-emitting element 1 of this embodiment includes a substrate 10, which includes a front surface 10A and a back surface 10B, wherein the front surface 10A has a plurality of metal foil traces 12, such as front foil trace 12A and front foil trace 12B, and the opposite back surface 10B also has a plurality of back foil trace 14, such as back foil trace 14A and back foil trace 14B. In addition, the substrate 10 also contains a plurality of metal pillars 16, wherein the front metal foil trace 12 and the back metal foil trace 14 can be made of metals with good thermal and electrical conductivity, and common materials such as copper, silver, aluminum, tungsten, gold, tin, etc. are not limited to these.

It is worth noting that the material of the substrate 10 in this invention is, for example, a polyimide (PI) plastic substrate instead of a common ceramic substrate. As mentioned in the prior art, the general ceramic substrate has good thermal conductivity, but poor ductility, so the thickness of the ceramic substrate cannot be made too thin, otherwise it is easy to crack. For example, plastic substrate such as PI substrate has the advantage of good ductility, but its disadvantage is insufficient thermal conductivity. Therefore, the substrate 10 in FIG. 1 is made of PI with good ductility. In this embodiment, the thickness of the substrate 10 is preferably less than 25 microns (μm), and the thickness of the substrate 10 plus the thickness of the front metal foil trace 12 and the back metal foil trace 14 is about 80 microns, that is, the total thickness is also controlled within 100 microns (0.1 mm). This thickness is greatly smaller than the total thickness of the conventional substrate for packaging light-emitting elements (the total thickness of the conventional substrate for packaging light-emitting elements is about 150 microns to 500 microns), so it is beneficial to the thinning of the packaged light-emitting elements and electronic devices.

In addition, the conventional packaged light-emitting elements which only use plastic as the substrate usually face the problem of insufficient heat dissipation even though the thickness of the substrate can be made thinner. In this invention, in order to improve the heat dissipation of a plastic substrate (such as PI), a plurality of metal pillars 16 are embedded in the substrate 10, wherein the material of the metal pillars 16 can be the same as that of the front metal foil trace 12 or the back metal foil trace 14. It is worth noting that the metal pillar 16 can be used as an electrical connection element between the front metal foil trace 12 and the back metal foil trace 14, as well as a heat dissipation element in this invention. For example, the heat energy generated during the operation of packaged light-emitting elements or electronic devices (such as arithmetic integrated circuits) can be quickly transferred from the front metal foil trace 12 to the back metal foil trace 14 (or vice versa) by the metal pillars 16, so as to improve the heat dissipation performance and the reliability of the devices.

Please continue to refer to FIG. 1, the packaged light-emitting element 1 further includes a light-emitting element 20, such as a light emitting diode, or further includes an organic light emitting diode (OLED), a submillimeter light emitting diode (mini LED), a micro LED or a quantum dot LED, but it is not limited to this. The light-emitting element 20 can emit monochromatic or multi-color mixed light, such as red light, blue light, green light or other mixed light (white light, etc.) composed of multiple colors, and the present invention is not limited to this. Or in other embodiments, it may include a plurality of light-emitting elements 20, such as an LED chip composed of red, green and blue (RGB) or an LED chip composed of red, green, blue and white (RGBW), all of which belong to the scope of this invention. In some embodiments, one packaged light-emitting element 1 can be provided with single or multiple light-emitting elements 20, and the invention does not limit the number of light-emitting elements 20 provided in one packaged light-emitting element 1.

It is worth noting that when designing the pins of the light-emitting element 20 in this embodiment, the pins are designed to correspond to the positions of the front metal foil traces 12A and 12B, that is to say, the light-emitting element 20 can be directly and electrically connected with the front metal foil traces 12A and 12B without forming additional metal wires. Generally, this kind of packaging is also called flip chip packaging. Other technical features of flip-chip packaging belong to the conventional technology in this field, so they will not be repeated here.

In addition, in some embodiments, the packaged light-emitting element 1 may additionally include a control integrated circuit (IC) for controlling the light-emitting element 20, but for the sake of brevity, the position of the IC is not shown in FIG. 1, and the related knowledge and technology about the IC belong to the conventional technology in the field, so it will not be repeated here.

It is worth noting that the metal pillars 16 of this invention are different from the conductive vias (often called vias or plugs) which penetrate through the substrate and are used to connect the front foil traces and the back foil traces in the prior art, and have obvious differences in arrangement and distribution. Furthermore, since the conventional conductive plug (or via) is only used to electrically connect the front foil traces and the back foil traces together, a group of metal foil traces on the front and back sides only need a single conductive plug (or via) to connect. In the present invention, due to the need to improve the heat dissipation effect of the components, a plurality of metal pillars 16 are included between each group of the front foil traces and the back foil traces to connect the front metal foil trace 12 and the back metal foil trace 14 at the same time, so as to improve the heat dissipation effect and achieve the conductivity effect. More specifically, taking FIG. 1 as an example, a plurality of metal pillars 16 are included between the front metal foil trace 12A and the back metal foil trace 14A. These metal pillars 16 directly contact the front metal foil trace 12A and the back metal foil trace 14A, which can not only electrically connect the front metal foil trace 12A and the back metal foil trace 14A, but also achieve the effect of improving heat dissipation. Similarly, a plurality of metal pillars 16 are also included between the front metal foil trace 12B and the back metal foil trace 14B in FIG. 1.

In addition, another difference between the conventional via plug and the metal pillars in this case is the number and density of distribution. In the present invention, in order to improve the heat dissipation, it is better to increase the number of metal pillars as much as possible, that is, to place more metal pillars between the front foil traces and the back metal foil traces. In addition, the metal pillars 16 of this invention may also contain some metal pillars 16 which are not electrically connected with any metal foil traces to form dummy structures, that is to say, the metal pillars 16 can still be contained at the positions where no metal foil traces are formed, and these metal pillars 16 can still achieve the effect of improving heat dissipation. The above structure also belongs to the scope of the present invention.

In other embodiments of this invention, other shapes of metal elements can also be used instead of metal pillars, such as metal mesh, metal sheet, etc. These elements can achieve the effects of electric conduction and heat conduction, and all of them are within the scope of this invention.

The light-emitting element 1 further comprises a protective layer 30 covering the front surface 10A of the substrate 10, the front metal foil traces 12A and 12B and the light-emitting element 20, wherein the protective layer 30 comprises a transparent insulating material such as silicone or epoxy resin. The protective layer 30 can be used to fix the position of the light-emitting element 20, and can prevent external dust or moisture from contacting the light-emitting element 20, thus achieving the effect of protecting the element.

The following description will detail the different embodiments of the packaged light-emitting element of the present invention. To simplify the description, the following description will detail the dissimilarities among the different embodiments and the identical features will not be redundantly described. In order to compare the differences between the embodiments easily, the identical components in each of the following embodiments are marked with identical symbols.

In the above embodiment, the light-emitting element 20 directly contacts the front metal foil traces 12A, 12B, so there is no need to form additional wires to connect the light-emitting element 20. However, in the above embodiment, the pins of the light-emitting element 20 must match the patterns of the front metal foil traces 12A, 12B.

In other embodiments of this invention, wires can also be arranged according to requirements to connect the front metal foil trace with the light-emitting elements, so that the arrangement of the elements is more flexible. FIG. 2 shows a schematic cross-sectional structure of a packaged light-emitting element according to a second preferred embodiment of the present invention. The structure of the packaged light-emitting element 2 of this embodiment is substantially similar to that of the first preferred embodiment described above. The substrate 10 is also made of PI. The front surface 10A of the substrate 10 includes a plurality of front metal foil traces 12, such as front metal foil trace 12C, front metal foil trace 12D and front metal foil trace 12E, and the back surface 10B of the substrate 10 includes a plurality of back metal foil traces 14, such as back metal foil trace 14C, back metal foil trace 14D and back metal foil trace 14E. In addition, a plurality of metal pillars 16 are embedded in the substrate 10, which are used for electrically connecting the front and back metal foil traces and improving the heat dissipation effect of the components. The light-emitting element 20 is disposed on the front surface 10A of the substrate 10 and includes a protective layer 30.

In this embodiment, a plurality of metal wires 40 are also included, and the metal wires 40 here are different from the above-mentioned metal foil traces, and can be suspended without being attached to the substrate 10. The metal wire 40 electrically connects the light-emitting element 20 and some front metal foil traces (for example, the front metal foil trace 12C and the front metal foil trace 12E). The metal wire 40 can flexibly electrically connect the light-emitting element 20 and part of the front metal foil trace, without designing the pins of the light-emitting element 20 to correspond to the metal foil trace. In other words, if the pins of the light-emitting element 20 do not match the pattern of the front metal foil trace 12, it can be compensated by the metal wires 40.

As shown in FIG. 2, a plurality of metal pillars 16 are included between the front metal foil trace 12C and the back metal foil trace 14C. These metal pillars 16 directly contact the front metal foil trace 12C and the back metal foil trace 14C, which can not only electrically connect the front metal foil trace 12C and the back metal foil trace 14C, but also achieve the effect of improving heat dissipation. Similarly, in FIG. 2, a plurality of metal pillars 16 are also included between the front metal foil trace 12D and the back metal foil trace 14D, and between the front metal foil trace 12E and the back metal foil trace 14E. Another noteworthy point is that in this embodiment, because there are more metal wires 40, the light-emitting element 20 is actually electrically connected to the front metal foil trace 12C and the front metal foil trace 12E by the metal wires 40, while the front metal foil trace 12D may not be electrically connected to the light-emitting element (forming a similar dummy structure). However, even if the front metal foil trace 12D is not electrically connected to the light-emitting element 20, the metal pillar 16 located between the front metal foil trace 12D and the back metal foil trace 14D can still achieve the effect of improving heat dissipation. However, in other embodiments of the present invention, the metal pillar 16 between the front metal foil trace 12D and the back metal foil trace 14D may be omitted as required, which is also within the scope of the present invention.

According to the above description and drawings, the present invention provides a packaged light-emitting element, which comprises a substrate 10, wherein the substrate 10 includes a front surface 10A and a back surface 10B, a light-emitting element 20 located on the front surface 10A of the substrate 10, and a plurality of metal pillars 16 embedded in the substrate 10.

In some embodiments of the present invention, metal foil traces are located on the front surface 10A and the back surface 10B of the substrate 10, wherein the metal foil trace located on the front surface 10A of the substrate 10 is defined as the front metal foil trace 12, and the metal foil trace located on the back surface 10B of the substrate 10 is defined as the back metal foil trace 14.

In some embodiments of the present invention, any front metal foil trace 12 and any back metal foil trace 14 include a plurality of metal pillars 16 located between them.

In some embodiments of the present invention, a plurality of metal pillars 16 directly contact the front metal foil traces (12A-12E) and the back metal foil traces (14A-14E).

In some embodiments of the present invention, the thickness of the substrate 10 is less than 25 micrometers, and the total thickness of the substrate 10, the front metal foil trace 12 and the back metal foil trace 14 is less than 0.1 mm.

In some embodiments of the present invention, a plurality of metal wires 40 are further included, which electrically connect the light-emitting element 20 with the front metal foil trace 12.

In some embodiments of the present invention, the material of the substrate 10 contains polyimide (PI) but does not contain ceramics.

In some embodiments of the present invention, the light-emitting element 20 includes a light emitting diode (LED).

In some embodiments of the present invention, a protective layer 30 is further included on the light-emitting element 20, wherein the protective layer 30 comprises silicone or epoxy resin.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A packaged light-emitting element, comprising:
a substrate, which comprises a front surface and a back surface;
a light-emitting element located on the front surface of the substrate; and
a plurality of metal pillars buried in the substrate.

2. The packaged light-emitting element according to claim 1, further comprising metal foil traces located on the front surface and the back surface of the substrate, wherein the metal foil traces located on the front surface of the substrate are defined as front metal foil traces, and the metal foil traces located on the back surface of the substrate are defined as back metal foil traces.

3. The packaged light-emitting element according to claim 2, wherein any one of the front metal foil traces and any one of the back metal foil traces includes a plurality of metal pillars located between them.

4. The packaged light-emitting element according to claim 3, wherein the plurality of metal pillars directly contact the front metal foil trace and the back metal foil trace.

5. The packaged light-emitting element according to claim 2, wherein the thickness of the substrate is less than 25 micrometers, and the sum of the thicknesses of the substrate, the front metal foil trace and the back metal foil trace is less than 0.1 mm.

6. The packaged light-emitting element according to claim 2, further comprising a plurality of metal wires electrically connecting the light-emitting element with the front metal foil trace.

7. The packaged light-emitting element according to claim 1, wherein the material of the substrate contains polyimide (PI) and does not contain ceramics.

8. The packaged light-emitting element according to claim 1, wherein the light-emitting element comprises a light emitting diode (LED).

9. The packaged light-emitting element according to claim 1, further comprising a protective layer on the light-emitting element, wherein the protective layer comprises silicone or epoxy resin.
